(19) United States
(12) Patent Application Publication
(10) Pub. No.: US 2026/0288018 A1
(43) Pub. Date: Sep. 24, 2026

(54) IMAGE PREPROCESSING METHOD FOR DETECTING AN ABNORMALITY

(71) Applicant: CANON KABUSHIKI KAISHA, Tokyo (JP)

(72) Inventors: Humberto BOCANEGRA EVANS, Austin, TX (US); Hiroshi Ebisuyu, Kawasaki-shi (JP); Kenneth Aird, Austin, TX (US)

(21) Appl. No.: 19/085,462

(22) Filed: Mar. 20, 2025

(51) Int. Cl. G03F 7/00

(52) U.S. Cl. CPC G03F 7/706841; G03F 7/706851

(57) ABSTRACT

A method for monitoring a spread front using a spread camera to detect an abnormality including receiving a series of images of interference fringes formed by reflections off a superstrate and a substrate as the superstrate conforms to the substrate while forming a film on the substrate with the superstrate, for each image in the series of images, extracting an annular set of pixels that form an annular shape including one or more of the interference fringes, converting each of the annular set of pixels into one or more rectangular sets of pixels of a rectangular shape, detecting a probability of an abnormality in any of the one or more rectangular sets of pixels and reporting the probability.

### BACKGROUND

### Field of Art

The present disclosure relates to a method of spread front detection and preprocessing for identifying any abnormalities. In particular, the method is directed to observing the spread front for distortion among the interference fringes over a sequence of images as a superstrate presses on formable material on a substrate during a nanoimprint lithography or inkjet adaptive planarization in real-time.

### Description of the Related Art

Planarization techniques are useful in fabricating semiconductor devices. For example, the process for creating a semiconductor device includes repeatedly adding and removing material to and from a substrate. Separately, substrates (e.g., silicon wafers, semiconductor wafers, ceramic wafers, glass wafers, quartz wafers, sapphire wafers, lithium niobate wafers, gallium arsenide wafers, silicon carbide wafers, indium phosphide wafers, germanium wafers, etc.) themselves are not always perfectly flat and may include an initial surface height variation (i.e., topography). One method of addressing this issue is to planarize the substrate prior to and/or between layering steps. Various lithographic patterning methods benefit from patterning on a planar surface. In ArFi laser-based lithography, planarization reduces the impact of depth of focus (DOF) limitations, and improves critical dimension (CD), and critical dimension uniformity. In extreme ultraviolet lithography (EUV), planarization improves feature placement and reduces the impact of DOF limitations. In nanoimprint lithography (NIL) planarization improves feature filling and CD control after pattern transfer.

A planarization technique sometimes referred to as inkjet-based adaptive planarization (IAP) involves dispensing a variable drop pattern of polymerizable material between the substrate and a superstrate, where the drop pattern varies depending on the substrate topography. A superstrate is then brought into contact with the polymerizable material after which the material is polymerized on the substrate, and the superstrate removed. Improvements in planarization techniques, including IAP techniques, are desired for improving, e.g., whole wafer processing and semiconductor device fabrication.

During the nanoimprint lithography (NIL) or inkjet-based adaptive planarization (IAP) process, particles or other contamination sources can land onto the substrate chuck. These unintended events may change the substrate chuck flatness which significantly affects the overlay in NIL and defect quality in NIL and IAP.

A known method in the art for detecting abnormalities in the spread front relies on calculating a line tangent to the spread front. If the direction of this tangent line deviates from an expected value, it is implied that an abnormality is deforming the spread front. A known issue associated with monitoring the spread front includes real-time analysis. The spread front images are typically too large to be used for real-time particle detection. Another issue is that the background of the spread front images interfere with detection of the anomaly. Finding the anomaly in a circular ring is difficult because the anomaly that may look like a kink in a circular ring does not have a defined direction. Additionally, the anomaly's shape (width, height, thickness, etc.) is difficult to capture in a model. Furthermore, the spread front moves outwardly at a variable speed which can further complicate extracting appropriate information for real-time particle detection.

Thus, there is a need in the art for real-time particle detection of substrate during an imprinting (shaping, patterning, or planarizing) process.

### SUMMARY

The present disclosure is directed to a method for real-time particle detection by obtaining and processing information near the spread front as well as accounting for the outward movement of the spread front at a variable speed. The position of the spread front is approximated and then this approximation is inputted into a machine learning model to detect an abnormality in the image. If an abnormality in the image is detected, then processing of the substrate may be stopped or a warning may be issued to the user about a particle being present that may be causing a defect or abnormality. The method includes receiving a series of images of interference fringes formed by reflections off a superstrate and a substrate as the superstrate conforms to the substrate while forming a film on the substrate with the superstrate. For each image in the series of images, extracting an annular set of pixels that form an annular shape including one or more of the interference fringes. Converting each of the annular set of pixels into one or more rectangular sets of pixels of a rectangular shape. The method also includes detecting a probability of an abnormality in any of the one or more rectangular sets of pixels and reporting the probability.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure, and are therefore not to be considered limiting of its scope, for the disclosure may admit to other equally effective embodiments.

FIG. 1 is a schematic diagram illustrating an example planarization system in accordance with an aspect of the present disclosure.

FIGS. 2A to 2C illustrate a schematic cross section of an example planarization process in accordance with an aspect of the present disclosure.

FIG. 3 is a cross-sectional view illustrating a state of bringing a superstrate/mold/template and formable material into contact with each other.

FIGS. 4A to 4F are drawings illustrating a contact area between the mold/template and the formable material and an interference fringe in the periphery thereof.

FIG. 5 is a drawing illustrating a contact state among the detected interference fringe, the superstrate, and the substrate with a foreign particle between the superstrate and the substrate.

FIGS. 6A to 6C include exemplary images of a substrate with formable material during an imprinting sequence.

FIG. 7 is a flowchart outlining the steps for spread front detection and preprocessing for particle identification in accordance with an example embodiment.

FIG. 8 is a flowchart illustrating an exemplary imprinting method as used in an example embodiment.

FIGS. 9A-9C illustrate the relationship of the radial distance with respect to the angle of a non-concentric circle and the interference fringes in accordance with an example embodiment.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

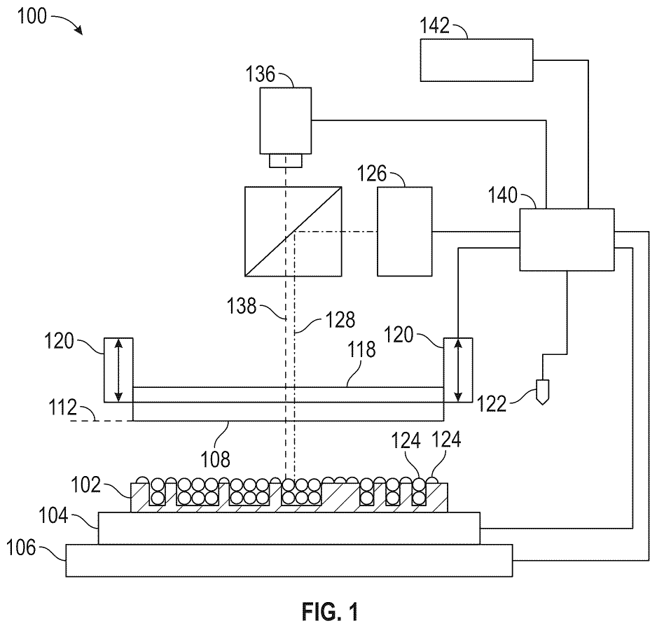

FIG. 1 illustrates an example system for shaping a film (for example planarization) in accordance with an aspect of the present disclosure. The shaping system 100 is used to shape (for example planarize or nanoimprint) a film on a substrate 102 on nanometer length scales. Non-limiting examples of shaping system 100 are a nanoimprint lithography system and an inkjet adaptive planarization system. The substrate 102 or wafer may be coupled to a substrate chuck 104. The term substrate chuck 104 may be used interchangeably throughout the specification with the term wafer chuck. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the x-, y-, z-, θ-, ψ, and φ-axes. The substrate positioning stage 106, the substrate 102, and the substrate chuck 104 may also be positioned on a base (not shown). The substrate positioning stage may be a part of a positioning system.

Spaced apart from the substrate 102 is a superstrate 108 (also referred herein as a plate) having a working surface 112 facing substrate 102. The superstrate 108 may be formed from materials including, but not limited to, fused silica, quartz, silicon, organic polymers, siloxane polymers, borosilicate glass, fluorocarbon polymers, metal, hardened sapphire, ceramic, glass, and/or the like. In an embodiment the superstrate is readily transparent to UV light. The working surface 112 is generally of the same area size or slightly smaller than the surface of the substrate 102. The working surface 112 can be substantially featureless in which case the superstrate 108 is used for planarization. The working surface 112 can also include a pattern of recesses and depressions which can be used to pattern a film on the substrate 102. The superstrate 108 can also be smaller than the substrate and used in a step and repeat manner on the substrate 102. When the superstrate 108 has a working surface 112 that includes a pattern of recesses and depressions then the superstrate may sometimes be referred to as a template.

The superstrate 108 may be coupled to or retained by a superstrate chuck assembly 118, which is discussed in more detail below. The superstrate chuck assembly 118 may be coupled to a shaping head 120 which is a part of the positioning system. The shaping head 120 may be movably coupled to a bridge. The shaping head 120 may include one or more actuators such as voice coil motors, piezoelectric motors, linear motor, nut and screw motor, etc., which are configured to move the superstrate chuck assembly 118 relative to the substrate 102 in at least the z-axis direction, and potentially other directions (e.g. x-, y-, θ-, ψ-, and φ-axis).

The shaping system 100 may further comprise a fluid dispenser 122. The fluid dispenser 122 may also be movably coupled to the bridge. In an embodiment, the fluid dispenser 122 and the shaping head 120 share one or more of all positioning components. In an alternative embodiment, the fluid dispenser 122 and the planarization head move independently from each other. The fluid dispenser 122 may be used to deposit droplets of liquid formable material 124 (e.g., a polymerizable material, a photocurable polymerizable material, a thermal curing polymerizable material, etc.) onto the substrate 102 with the volume of deposited material varying over the area of the substrate 102 based on at least in part upon its topography profile. Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that includes a radiation source 126 that directs actinic energy, for example, UV radiation, along an exposure path 128. The shaping head 120 and the substrate positioning stage 106 may be configured to position the superstrate 108 and the substrate 102 in superimposition with the exposure path 128. The radiation source 126 sends the actinic energy along the exposure path 128 after the superstrate 108 has contacted the formable material 124. FIG. 1 shows the exposure path 128 when the superstrate 108 is not in contact with the formable material 124. This is done for illustrative purposes so that the relative position of the individual components can be easily identified. An individual skilled in the art would understand that exposure path 128 would not substantially change when the superstrate 108 is brought into contact with the formable material 124.

The shaping system 100 may further comprise a camera 136 (also referred to as a spread camera or a field camera) positioned to view the spread of formable material 124 as the superstrate 108 contacts the formable material 124 during the planarization process. FIG. 1 illustrates an optical axis 138 of the field camera's imaging field. As illustrated in FIG. 1, the shaping system 100 may include one or more optical components (dichroic mirrors, beam combiners, prisms, lenses, mirrors, etc.) which combine the actinic radiation with light to be detected by the camera 136. The camera 136 may include one or more of a CCD, a sensor array, a line camera, and a photodetector which are configured to gather light at a wavelength that shows a contrast between regions underneath the superstrate 108 and in contact with the formable material 124 and regions underneath the superstrate 108 but not in contact with the formable material 124. The camera 136 may be configured to provide images of the spread of formable material 124 underneath the superstrate 108, and/or the separation of the superstrate 108 from cured formable material 124. The camera 136 may also be configured to measure interference fringes, which change as the formable material 124 spreads between the gap between the working surface 112 and the substrate surface; and as the distance between the working surface 112 and the substrate surface changes.

The shaping system 100 may be regulated, controlled, and/or directed by one or more processors 140 (controller) in communication with one or more components and/or subsystems such as the substrate chuck 104, the substrate positioning stage 106, the superstrate chuck assembly 118, the shaping head 120, the fluid dispenser 122, the radiation source 126, and/or the camera 136. The processor 140 may operate based on instructions in a computer readable program stored in a non-transitory computer memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the method steps described herein may be executed by the processor 140.

In operation, either the shaping head 120, the substrate positioning stage 106, or both vary a distance between the superstrate 108 and the substrate 102 to define a desired space (a bounded physical extent in three dimensions) that is filled with the formable material 124. For example, the shaping head 120 may be moved toward the substrate and apply a force to the superstrate 108 such that the superstrate contacts and spreads droplets of the formable material 124 as further detailed herein.

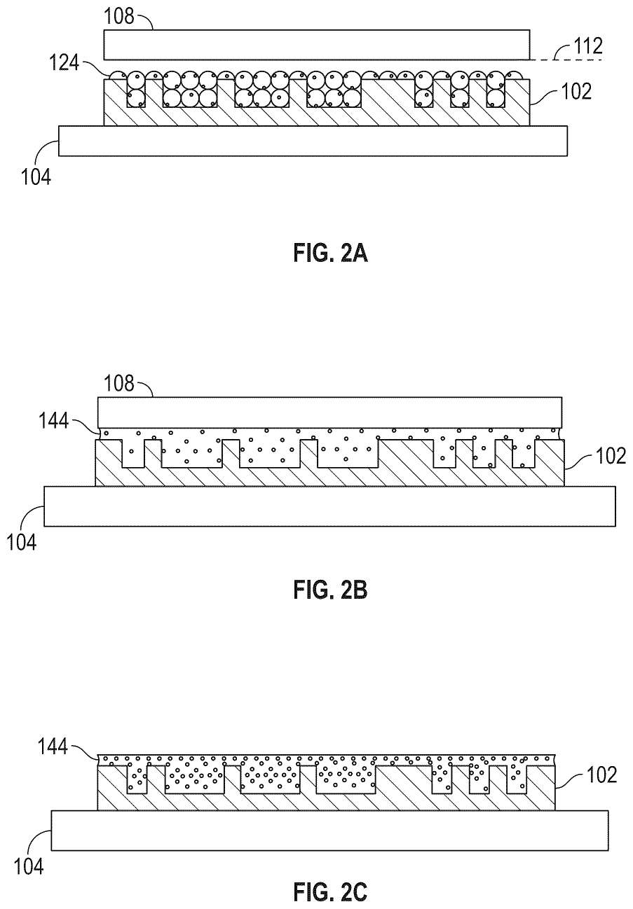

The planarization process includes steps which are shown schematically in FIGS. 2A-2C. As illustrated in FIG. 2A, the formable material 124 is dispensed in the form of droplets onto the substrate 102. As discussed previously, the substrate surface has some topography which may be known based on previous processing operations or may be measured using a profilometer, AFM, SEM, or an optical surface profiler based on optical interference effect like Zygo NewView 8200. The local volume density of the deposited formable material 124 is varied depending on the substrate topography. The superstrate 108 is then brought into contact with the formable material 124.

FIG. 2B illustrates a post-contact step after the superstrate 108 has been brought into full contact with the formable material 124 but before a polymerization process starts. As the superstrate 108 contacts the formable material 124, the droplets merge to form a formable material film 144 that fills the space between the superstrate 108 and the substrate 102. Preferably, the filling process happens in a uniform manner without any air or gas bubbles being trapped between the superstrate 108 and the substrate 102 in order to minimize non-fill defects. The polymerization process or curing of the formable material 124 may be initiated with actinic radiation (e.g., UV radiation). For example, radiation source 126 of FIG. 1 can provide the actinic radiation causing formable material film 144 to cure, solidify, and/or cross-link, defining a cured planarized layer 146 on the substrate 102. Alternatively, curing of the formable material film 144 can also be initiated by using heat, pressure, chemical reaction, other types of radiation, or any combination of these. Once cured, the cured planarized layer 146 is formed, the superstrate 108 can be separated therefrom. FIG. 2C illustrates the cured planarized layer 146 on the substrate 102 after separation of the superstrate 108. The substrate and the cured layer may then be subjected to additional known steps and processes for device (article) fabrication, including, for example, patterning, curing, oxidation, layer formation, deposition, doping, planarization, etching, formable material removal, dicing, bonding, and packaging, and the like. The substrate may be processed to produce a plurality of articles (devices).

One scheme for minimizing entrapment of air or gas bubbles between the superstrate 108 and the substrate 102 as the formable material 124 droplets spread, merge and fill the gap between the superstrate 108 and the substrate 102 is to position the superstrate 108 such that it makes initial contact with the formable material 124 in the center of the substrate 102 with further contact then proceeding radially in a center to perimeter fashion. This requires a deflection or bowing of the superstrate 108 or substrate 102 or both to create a curvature in the superstrate 108 relative to the substrate 102. The curvature of the superstrate 108 facilitates the expulsion of the air or gas bubbles as the formable material 124 spreads. Such a superstrate 108 profile can be obtained by, for example, applying a back pressure to the interior region of the superstrate. However, in doing so, a perimeter holding region is still required to keep the superstrate 108 retained on the superstrate chuck assembly 118. Given that the superstrate 108 is typically of the same or similar areal dimension as the substrate 102, if both the perimeter edges of the superstrate 108 and the substrate are 102 chucked flat during formable material 124 droplet spreading and merging, there will be no available superstrate curvature profile in this flat chucked area. This may compromise the droplet spreading and merging, which may also lead to non-fill defects in the region. To minimize non-fill defects, the superstrate curvature needs to be controlled over the full superstrate diameter during the fluid spreading process. In addition, once spreading and filling of the formable material is complete, the resultant stack of a superstrate chuck, a chucked superstrate, the liquid formable material film, substrate, and a substrate chuck can be an over-constrained system. This may cause a non-uniform planarization profile of the resultant planarized film layer. That is, in such an over-constrained system, all flatness errors or variations from the superstrate chuck, including front-back surface flatness, can be transmitted to the superstrate and impact the uniformity of the planarized film layer. Additionally, at the time of separating the superstrate from the cured film, it is desirable to achieve a consistent circumferential separation front between the superstrate and the cured film.

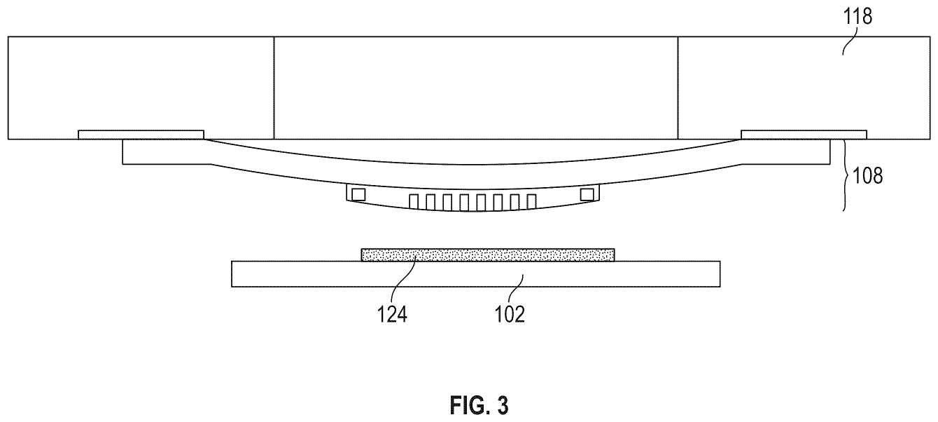

FIG. 3 illustrates a state in which a superstrate 108 (in which the working surface 112) is curved to project toward the substrate 102. As a method of curving the superstrate 108 (surface of the pattern), a method of applying pressure from the superstrate chuck assembly 118 that holds the superstrate 108 is exemplified. A space between the superstrate 108 and the superstrate chuck assembly 118 is a closed space, and the superstrate chuck assembly 118 is provided with a mechanism configured to vary the pressure (air pressure) in the space. The shaping apparatus of the embodiment brings part of the working surface 112 into contact with the formable material 124 on the substrate in a state in which the superstrate 108 is curved as illustrated in FIG. 3. After part of the working surface 112 (which may include a pattern) has been brought into contact with the formable material 124, the formable material 124 is brought into contact with an entire surface of the working surface 112 so as to increase the contact surface area between the working surface 112 and the formable material 124 while straightening the superstrate 108 curved into a convex shape (canceling the curvature). By bringing the superstrate 108 into contact with the formable material 124 in the curved state, air bubbles are less likely to be trapped between the formable material film and the concave working surface 112.

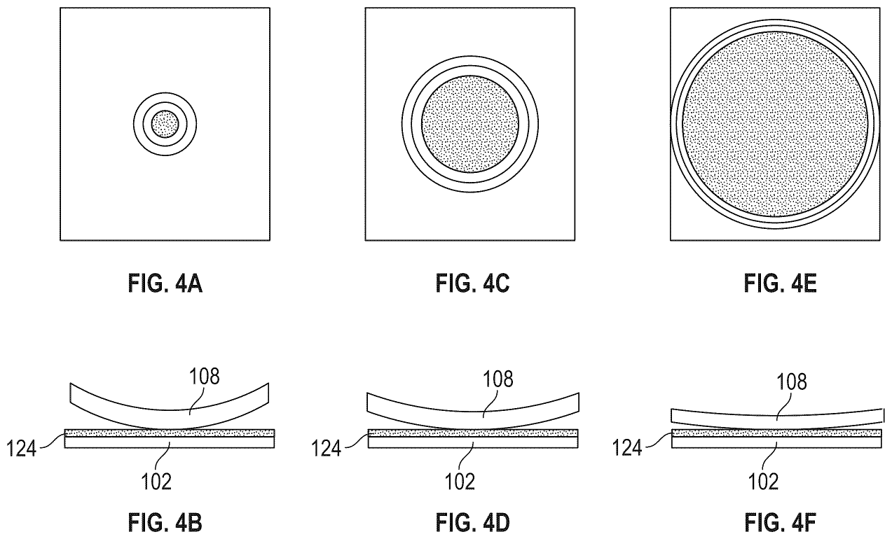

FIGS. 4A to 4F are drawings illustrating the contact state in which the superstrate 108 is brought into contact with the formable material 124 in the curved state. FIGS. 4A to 4F illustrate a state in which no foreign substance (particle) is present between the superstrate 108 and the substrate 102. FIGS. 4A, 4C, and 4E illustrate observed images detected by the camera 136 of the shaping system 100 when bringing the superstrate 108 into contact with the formable material 124, respectively. FIGS. 4B, 4D, and 4F illustrate cross sections of the superstrate 108 and the substrate 102, respectively.

FIG. 4A illustrates a state in which the superstrate 108 is curved (deformed), and the working surface 112 (which may include a pattern) is brought into a first contact with the formable material 124. The lowest point of the working surface 112 in the convex shape is in contact with the formable material 124. At this time, the observed image observed by the camera 136 includes an area where the working surface 112 and the formable material 124 are in contact with each other (solid area at a center), and interference fringes caused by interference of light in the periphery thereof. FIG. 4B illustrates a cross section of the superstrate 108 and the substrate 102 at this time.

By straightening the superstrate 108 gradually into a flat surface after the working surface 112 and the formable material 124 have come into contact with each other, a contact surface area between the working surface 112 and the formable material 124 is increased. FIGS. 4C and 4E illustrate a state in which the contact surface area between the working surface 112 and the formable material 124 is increased. A state in which the contact surface area between the working surface 112 and the formable material 124 is uniformly (concentrically) increased from the center of the pattern portion toward the peripheral portion is illustrated.

FIGS. 4D and 4F illustrate cross sections of the superstrate 108 and the substrate 102 corresponding to FIGS. 4C and 4E, respectively. It is understood that the contact surface area between the working surface 112 and the formable material 124 is increased as the curvature of the superstrate 108 is gradually straightened. The interference fringes seen in the periphery of the area where the superstrate 108 and the formable material 124 are in contact with each other is also spread corresponding to the increase of the contact surface area. The interference fringe is generated by interference between light reflected from the working surface 112 and light reflected from the surface of the substrate 102. Finally, the working surface 112 and the formable material 124 come into contact with each other over the entire surface of the shaping area (shot area) (which may be either a whole substrate or a portion of the substrate), the interference fringe is not seen any longer. When the working surface 112 and the formable material 124 come into contact with each other, since there is little difference in refractive index between the superstrate 108 and the formable material 124, light is not substantially (less than 0.01%) reflected by the working surface 112, and hence the intensity variation of the interference fringe is very small and cannot be seen any longer.

In a portion in which the superstrate 108 and the formable material are in contact with each other, the formable material is present between the superstrate 108 and the substrate 102. As described above, since there is little difference in refractive index between the superstrate 108 and the formable material, not much light is reflected by the surface of the superstrate 108 at the working surface 112/formable material 124 interface. Therefore, the interference fringe is substantially not detectable in the area in which the superstrate 108 and the formable material are in contact with each other. A bright and dark ring pattern similar to a Newton's ring (also known as interference fringes), in which several bright and dark rings are repeated in a concentric fashion, appears in the periphery of the contact portion between the superstrate 108 and the formable material 124. The contact state between the formable material 124 and the superstrate 108 is observed by using the interference fringes.

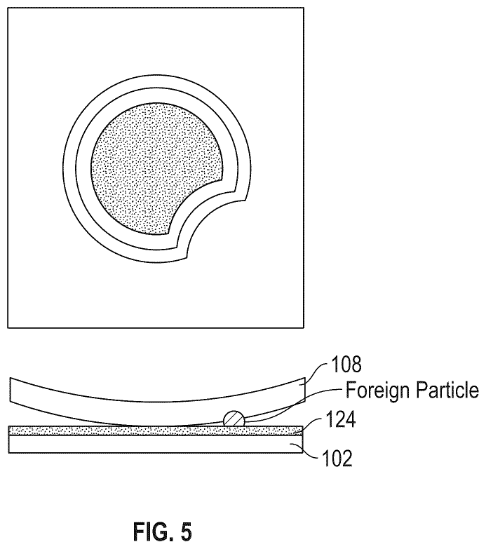

FIG. 5 illustrates a cartoon of a contact area picked up by the camera 136 and the interference fringes in the periphery thereof when a foreign particle is located between the superstrate 108 and the formable material 124. In FIG. 5, the contact area and the interference fringe generated in the periphery thereof observed when the superstrate 108 and the formable material 124 are brought into contact with each other has a shape deviating from the circular shape (deformed shape). This can be because an air bubble or a foreign substance (for example a particle) is present between the superstrate 108 and the substrate 102. The contact area and the interference fringe in the periphery thereof spread from the center of the shot area to the peripheral portions in a concentric fashion as illustrated in FIGS. 4A to 4F. However, the interference fringe cannot have a concentric circular shape due to an air bubble or a foreign substance present between the superstrate 108 and the substrate 102. The applicant has found when the superstrate 108 is thin (less than 1 mm), the superstrate will deform around the foreign particle causing interference fringes to appear around the foreign particle after the superstrate makes contact with the formable material around the foreign particle.

As a method of detecting an interference fringe deformed from the concentric circular shape includes using a camera 136 and software to monitor a spread camera image showing spread front distortion. The interference fringes detected by the camera 136 do not directly measure the spread front, but they are correlated with the spread front. During a contact stage of a shaping process a brightness peak of the zero order bright fringe will be slightly outside a distance Δβ₀ in the radial direction of the spread front depending on the angle ψr (typically less than 1°) of the working surface 112 with the substrate 102 in the radial direction and a thickness Δz of the film being formed (Δβ₀=(λ/4−Δz)/tan(ψr)). A similar calculation based on the expression above can be used when different fringes are tracked. The working surface 112 and/or the substrate 102 will typically have subwavelength features which will cause consistent but non-uniform scattering of the measurement light that is creating the interference fringes, this will add some noise to the measurement process which can be compensated by averaging. The spread camera image is of the interference fringes detected by the camera 136 when bringing the superstrate 108 and the formable material 124 into contact with each other. In the normal state illustrated in FIGS. 4A to 4F, the circular shape indicating the contact area of the interference fringe does not change. It is also possible to obtain the change of the interference fringe at the time of normal pattern transfer as illustrated in FIGS. 4A to 4F in advance and compare the changes at every pattern transfer. Since deformation of the interference fringe from the concentric circular shape is sensed, calculation of the difference from the interference fringe obtained at a normal shot is conceivable. By the comparison with the pattern at every pattern transfer, the contact state, that is, a time period required for the formable material to spread over the area in which the pattern is formed from the first contact (spreading time) may be obtained. The size of the contact area after a predetermined time period has elapsed from the start of contact at the normal pattern transfer illustrated in FIGS. 4A to 4F may be obtained in advance. Therefore, the result of image picked up by the camera when a predetermined period has elapsed after the first contact and the pattern obtained in advance are compared, and whether the time required for the contact area to spread is short or long may be obtained from the difference in size in comparison with that at the time of normal pattern transfer. If the air bubble remains between the template and the substrate, defective pattern transfer results. Therefore, the corresponding shot or substrate becomes a defective shot or defective planarization. Since the probability of the defective shot or defective planarization may be pointed out in advance, the corresponding shot area or substrate may be intensively inspected at a defect inspection after a shaping process. If the foreign substance is present therebetween, the superstrate 108 may have become damaged, for example, the working surface 112 may be broken by the foreign substance attached to the superstrate 108. If the working surface 112 is transferred to another shot area or another substrate with the foreign substance attached to the superstrate 108, defective transfer patterns or planarization may occur repeatedly.

Therefore, when the contact area and the interference fringe in the periphery thereof detected by the camera 136 are deformed from the concentric circular shape as illustrated in FIG. 5, the shaping process is preferably stopped immediately in order to avoid damage on the superstrate 108 or the substrate 102. However, since a process from the contact between the superstrate and the formable material 124 until the filling of the entire surface of the superstrate with the formable material 124 is performed in a very short time, there may be a case where the shaping process cannot be stopped.

Therefore, when the shaping process cannot be stopped in the course of contact, the foreign substance needs to be removed by replacing the superstrate 108 and cleaning after the pattern transfer or planarization. Since there is a probability that the working surface 112 of the superstrate 108 is broken, inspection of the working surface 112 is also required. By detecting the contact state, necessity of cleaning of the superstrate 108 or inspection of the working surface 112 as above described may be found.

Depending on the case, since the superstrate 108 or the substrate 102 may be curved locally by the presence of the foreign substance, and the interference fringe may be generated around the foreign substance, the foreign substance may be detected by using this phenomenon. Furthermore, the state of formable material 124 supplied (applied) onto the substrate 102 may be detected by observing how the interference fringe spreads. When the amount of supply of the formable material 124 is large, the distance between the superstrate 108 and the substrate 102 is increased, and when the amount of supply of the formable material 124 is small, the distance between the superstrate 108 and the substrate 102 is small. The interference fringe generated differs depending on the distance between the superstrate 108 and the substrate 102. Therefore, by observing the difference in the interference fringes, the cases where the amount of the formable material 124 supplied onto the substrate 102 is large or small may be detected to adjust the amount of supply or the position of supply (distribution) of the formable material 124.

As previously stated, normally, the spread front observed in the interference fringes by the camera 136 should be a circle. However, when the substrate chuck flatness is changed due to a particle of foreign substance, prior to contact the local distance between the working surface 112 and the substrate surface changes. While after the working surface 112 contacts the formable material at a specific location the interference fringes substantially disappear unless there is a particle or foreign substance between the working surface 112 and the substrate surface. In addition, if there is a substantial refractive index difference between the formable material and the superstrate which causes an interference signal to be detectable, a variation in the substrate chuck flatness will not show up as interference fringes if the superstrate is thin enough (<1 mm) to conform to the substrate. This change in local distance leads to a distorted spread front. Such spread front distortion on the camera 136 may be detected by image analysis software executed by the processor 140 to detect locations of an abnormality. The image analysis software may detect the circular objects in the image, fit the circular objects to perfect circles and calculate the amount of deviation (distortion) of the circular objects from the perfect circles. The image analysis software may also use machine learning methods to identify the positions of one or more interference fringes in each image. The machine learning method may be a neural network. The machine learning method may be an object detection neural network. The objects being identified may be arc segments of an interference fringe. Non-limiting examples of neural networks are: Resnet-32, YOLOX, YOLOR, YOLOv4, YOLOV7, OpenAi CLIP, VGG, DenseNet, Inception GoogLeNet, SqueezeNet, MobileNet, ShuffleNet, R-CNN, Fast R-CNN, Faster R-CNN, Mask R-CNN, Mesh R-CNN, and EfficientNet. The neural network may be trained on labeled image data in which individual pixels are labeled as being part of an interference fringe or not. The image analysis software may identify only bright fringes, only dark fringes or both. The image analysis software may be designed to identify only fringes of one or more specific orders.

When the location of the spread front is identified, the image analysis software may be used to extract the region where the spread front is imaged and transform it from polar to Cartesian coordinates. Then the output image (otherwise referred to as a slice) may be passed to a machine learning model in full form or sliced into smaller segments. The machine learning model may return the position and the type of abnormality detected, or a binary classifier that returns a true/false detection of an abnormality in the image or slice fed into the model. A user or the processor(s) 140 can use the results from the machine learning algorithm to stop processing of the substrate. If the position of the abnormality is returned, a backward transformation can be carried out in order to give the user the position within the substrate (x, y) or (r, angle).

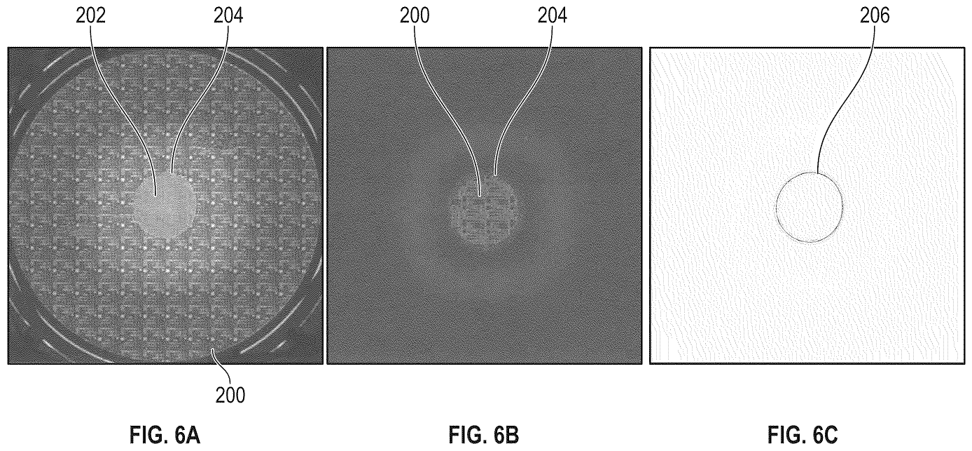

Referring now to FIG. 6A, a raw image is shown from the spread camera 136. The raw image includes the substrate 200, the formable material 202 spreading in a circular manner as well as the spread front 204. Using the raw image from FIG. 6A as shown to detect an abnormality near an interference fringe is not feasible in real-time due to the size of the image and variations in intensity due to the variation in reflectivity of the patterned substrate and the partially planarized film. Although the image shown is a static raw image, if a video image were shown, it would show that the formable material continues to spread in the circular shape covering more of the substrate during spread time. To reduce the size of the image, the background may be subtracted from the raw image as shown in FIG. 6B. The image in FIG. 6B essentially removes the substrate from the image except for the area covered by the formable material from the raw image in FIG. 6A. The image in FIG. 6B includes the substrate 200 as well as the spread front 204. Subtracting the background from the raw image reduces the size of the image but is still not the preferable image to use for detecting abnormalities in real-time in accordance with the present disclosure. Due to small feature sizes and submicron variations in depth, both interference and diffraction effects appear in the images obtained by the spread camera. These variations in light also affect the interference fringes due to variations in reflections from the patterned substrate variations of the angle of the reflected light due to scattering and diffraction. These variations change depending on where the spread front is located on the wafer. The applicant has found that these variations are high enough that they make the use of a single background reference image ineffective at isolating the interference fringes associated with the spread front from the rest of the background information. The information near the spread front is important for detecting abnormalities as the superstrate presses on the substrate. However, because the background changes as the spread front of the formable material advances during spread time, a background subtraction of the raw image does not work well and is not the ideal solution for identifying potential particles from the spread front images. In other words, because the spread front moves outwardly at a variable speed, the optical properties of the material inside the spread front are different from those outside of it, and the effect of light from the patterned substrate changes as the spread front moves, it is difficult to extract the information near the spread front by merely subtracting the background from a raw image.

Referring now to FIG. 6C, an image is shown where a previous raw image is subtracted from a current raw image. The method of subtracting a previous raw image from the current raw image as shown in FIG. 6C is a preferred method of the present disclosure. It is important to note that the image to be subtracted from the current raw image does not have to be immediately previous to the current raw image. The image used to subtract from the current image may be from a few images previous to the current image. One factor that may determine which image is selected to subtract from the current image is the quality of the image and how well the image captures changes in the interference fringes. Ideally, if the image quality is not an issue, the image selected from a sequence of images would include the previous image from the current image to account for the advancement of the spread front in a more accurate manner. The previous raw image used in the subtraction step can be selected based on one or more of: the spread front velocity; the frame rate; and the spread camera resolution. The previous raw image used in the subtraction step can be selected such that spread front moves at least 1 pixel. FIG. 6C with the previous image subtract reveals the important information around the spread front, namely, the first interference fringe 206. Every image in the planarization sequence of images contains one spread front. From a raw image, the previous images is subtracted to identify the location of the spread front. As shown in FIG. 6C, the amount of information to be processed from the image is significantly reduced compared with the image from FIGS. 6A and 6B. The image shown in FIG. 6C is better suited for detecting an abnormality due to a particle by analyzing the information near the spread front in real-time.

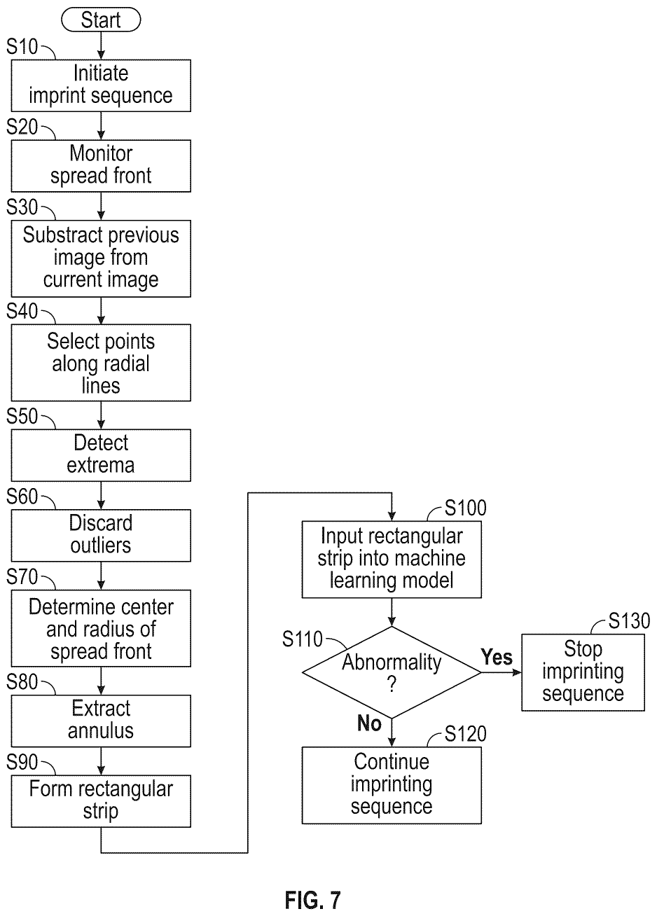

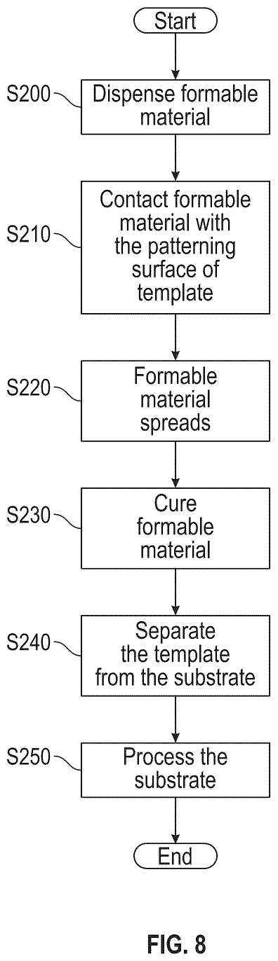

Referring now to FIG. 7 is a flowchart of various steps for spread front detection of formable material on a substrate to detect a foreign substance. Since images are too large to process in real-time, the present disclosure focuses on the information near the spread front in order to detect any abnormalities in as the superstrate presses on the substrate. The present disclosure takes into consideration the variable speed at which the spread front moves outwardly during the shaping or imprinting process. The method includes initiating the imprint sequence which is also known as the shaping process in step S10. The details of step S10 are discussed below with respect to FIG. 8 which outlines the various steps associated with the imprint sequence or shaping process.

Referring to FIG. 8 is a flowchart of a method of manufacturing an article that includes a shaping process by the shaping system 100 that can be used to shape the formable material 124 on the substrate. The shaping process may be performed repeatedly on a plurality of substrates 102 by the shaping system 100. The processor 140 may be used to control the shaping process. The shaping process may be a method of shaping a film layer. The film layer may be a planarization layer or a patterned layer.

The beginning of the shaping process may include a superstrate mounting step causing a superstrate conveyance mechanism to mount a superstrate 108 onto the superstrate chuck 104. The shaping process may also include a substrate mounting step, the processor 140 may cause a substrate conveyance mechanism to mount the substrate 102 onto the substrate chuck 104. The substrate 102 may have one or more coatings and/or structures. The order in which the superstrate 108 and the substrate 102 are mounted onto the shaping system 100 is not particularly limited, and the superstrate 108 and the substrate 102 may be mounted sequentially or simultaneously. A single superstrate 108 may be used to shape formable material on a plurality of substrates.

In a positioning step, the processor 140 may cause one or both of the substrate positioning stage 106 and/or a dispenser positioning stage to move the substrate 102 relative to a fluid dispense position below the fluid dispenser 122. In a dispensing step S200, the processor 140 may cause the fluid dispenser 122 to dispense formable material onto the substrate 102. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The substrate may be moved relative to the fluid dispenser 122 while the fluid dispenser is ejecting formable material 124. In an embodiment, during the dispensing step S200, the formable material 124 may be dispensed onto a substrate in accordance with drop pattern received from the processor 140 and stored in the memory 142. The drop pattern may include information such as one or more of position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets.

After, the droplets are dispensed, in an additional positioning step, the processor 140 may cause one or both of the substrate positioning stage 106 and/or a superstrate positioning stage to move the substrate 102 relative to the superstrate. During step S210 the imprint head lowers the superstrate chuck and pressure is applied to the back surface of the superstrate bowing out the superstrate, this is done over a period time as the superstrate is gradually flattened and the entire superstrate is in contact with the formable material.

During step S210 the processor 140 may cause an initial portion of the superstrate 108 to come into contact with the formable material 124 on the substrate 102.

During a spreading step S220, the formable material 124 then spreads out towards the edge of the substrate over a spreading period. How the formable material 124 spreads and fills the substrate surface can be observed via the spread camera 136 and may be used to track a progress of a spread front of formable material.

In a curing step S230, the processor 140 may send instructions to the radiation source 126 to send a curing illumination pattern of actinic radiation along the exposure path through the shaping surface. The curing illumination pattern provides enough energy to cure (polymerize, solidify, etc.) the formable material 124 under the shaping surface. The curing step S230 may be considered to end when the formable material 124 no longer receives actinic radiation from the radiation source 126.

In a separation step S240, the processor 140 uses one or more of the substrate chuck 104, the substrate positioning stage 106, superstrate chuck assembly 118, and the shaping head 120 to separate the shaping surface from the cured formable material on the substrate 102. In an embodiment, the separation step S240 is performed after the curing step S230 has finished.

In an embodiment, after the shaping process is finished additional semiconductor manufacturing processing is performed on the substrate 102 in a processing step S250 so as to create an article of manufacture (e.g. semiconductor device). In an embodiment, each substrate 102 includes a plurality of devices.

The further semiconductor manufacturing processing in processing step S250 may include etching processes to transfer a relief image into the substrate that corresponds to the pattern in the cured layer or an inverse of that pattern. The further processing in processing step S250 may also include known steps and processes for article fabrication, including, for example, inspection, curing, oxidation, layer formation, deposition, doping, planarization, etching, formable material removal, dicing, bonding, packaging, and the like. The substrate 102 may be processed to produce a plurality of articles (devices).

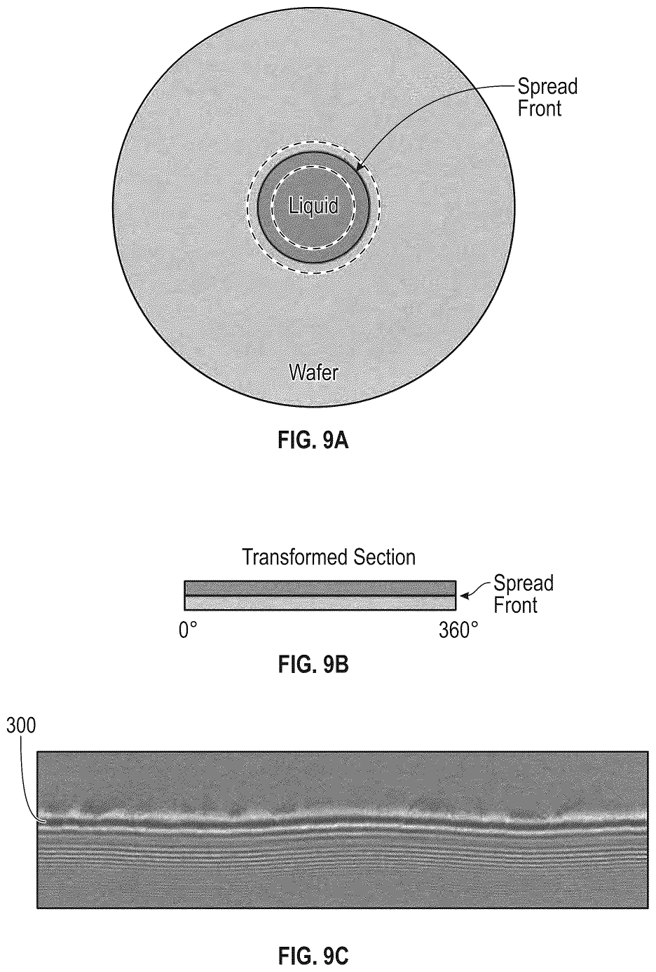

Referring back to FIG. 7, in step S20, the spread front is monitored by the camera 136 to obtain a sequence of images as the formable material spreads outwardly on the substrate in a circular shape while the superstrate presses onto the substrate. The camera 136 from FIG. 1 may be used to monitor the spread front in a series of images that when combined result in a video sequence. Thus, the series of images may be labeled with a time index i {i ε [symbol] ⁺: i ε [1,M]} from a time starting at 1 to the length of the series M (which may be between 2 and 10,000). Along with the time, the radius r_{i,1} to r_{i,N} and the angle θ_{i,1} to θ_{i,N} associated with the radius for every reference image i is included. Thus, for each image with time index i, there is an angle index j {j ε [symbol] ⁺: j ε [1,N]} associated with angles θ_{i,j} and radius r_{i,j}. The number of angle N can be 2 and 10,000 for example 3, 8, or 360. Since the spread front distortion of the interference fringes correspond to locations of extrema, it is informative to use the radial distances to determine the precise locations of the extrema for each image i. The angles θ_{i,1} to θ_{i,N} are central angles where the vertex of the angle is at the center of a concentric circle if no spread front distortion exists relatively to a fixed reference line. The sides of the angle lie on two radii of the circle. The measure of the central angle is the same as the measure of the arc that the two sides cut out of the circle. Each image can include multiple substantially circular interference fringes or arc segments. Each interference fringe will typically have some deviation from circularity (often referred to as roundness or eccentricity). In the present context, substantially circular means having radii that vary by 1-10%. FIG. 9A is an exemplary diagram illustrating an image that contains one spread front of the formable material (dark grey) spreading on the substrate (light gray) during the imprinting sequence.

Once some or all of the images of the spread front are obtained, in step S30, the previous image in the sequence of images is subtracted from the current image (Iᵢ-Iᵢ₋₁). Subtracting the previous image highlights the interference fringes in the spread front as shown and discussed with respect to FIG. 6C. In another embodiment of the present disclosure, an image used to subtract from the current image may be two or more images prior to the current image (Iᵢ-I_{i-b}). The value for temporal offset b can be selected based on one or more of: the spread front velocity; the frame rate of the spread camera; and the spread camera resolution. The temporal offset b can be selected such that spread front moves at least 1 pixel. The temporal offset b can vary with the temporal index i to compensate for variations in the spread front velocity. The interference fringes in the spread front have information that may be used to detect any abnormalities without having to process an entire image in real-time. Next, in step S40 radial lines are traced from the center of the substrate (or a center of initial contact as determined in a previous frame) in the image. Step S40 includes identifying a few points (10-5000) along radial lines starting at the center of the substrate. The lines are traced and one of the extrema (minimum or maximum) in the intensity profiles along these lines are detected in step S50. The extrema represent minimum and maximum positions of the interference fringe along the radial lines. When subtracted images are used instead of the raw images the extrema do not line up with the interference fringes and are instead offset based on motion of the spread front and the width of the interference fringes. These points along radial lines are fitted to a circle with an average radius R that approximates the position of the spread front. An annulus with the average radius R is extracted and transformed from cartesian to polar coordinates. In one embodiment, for each image i, 8 extrema points may be selected along the radial lines at different angles θ_{i,j} starting at the center of the substrate by way of example. However, more or less points (at least 2) may be selected depending on preference. In a preferred embodiment at least 8 points are selected for radial lines to be fitted to a circle in order to obtain an accurate approximation of the position of the spread front.

Next in step S60, some points from the points identified in step S40 are removed as outliers. In other words, points that are at a distance greater than a predetermined threshold of the radius may be determined as an outlier and removed. For example, the predetermined threshold may determine that points that are at a distance greater than 20% of the radius exceed the predetermined threshold and should be removed as outliers. While 20% is provided as an example, other values may be used as the predetermined threshold to determine the points that are outliers. In step S70, the image analysis software may rerun the least squares method or any other fitting method to a circle with the outliers removed to determine the radius and center coordinates of the spread front. In an embodiment, an initial guess for the center of the circle is the center of the substrate, this initial guess may be adjusted based on the fitting to coincide with a center of initial contact. This center of initial contact may then be used in step S40. Steps S40-S70 may be rerun if the center of initial contact is substantially different from the center of the substrate. Next in step S80, the annulus is extracted (R−m to R+n) that contains the spread front by extracting intensity lines along every pixel in the circumference of the circle. The annulus is defined by an inner ring radius (R−m) and an outer ring radius R+n, the annular ring width (m+n) is a difference between the outer ring and the inner ring. The average radius R is selected to be between the inner ring radius and the outer ring radius. The offsets m and n are selected to include most of the fringes visible in the subtracted image and a buffer region to include distortions inherent in the process. Each extracted segment becomes a column in the final image. FIG. 9B is an exemplary diagram of the rectangular strip or rectangular shape that is generated from the extracted annulus visually representing the spread front on the substrate from 0° to 360°. The rectangular strip or rectangular shape may be inputted into a machine learning model in its entirety from 0° to 360° or in multiple segments. The image will have dimensions (m+n)×c where c is the circumference of the circle in pixels. Then in step S90, a rectangular strip or rectangular shape is formed from the extracted annulus. In step S100, the rectangular strip or rectangular shape is input into a machine learning model for image analysis. The image analysis may identify kinks that are representative of particles to determine whether the shaping process should be stopped in real-time. FIG. 9C is an exemplary image that is output from the machine learning model to analyze the interference fringes 300 for any substantial kinks that represent an abnormality that could be caused by an unwanted particle on the substrate or superstrate. In step S110, the machine learning model determines if an abnormality is detected based on any identified kinks in the rectangular strip that represents the extracted annulus of the spread front. If it is determined that no abnormality is detected (NO in step S110), the imprint sequence or shaping process is continued in step S120. On the other hand, if it is determined that an abnormality is detected (YES in step S110), then the imprint sequence or shaping process is stopped is step S130. Stopping the shaping process (including imprinting or planarizing) can include removing the superstrate 108 from the shaping system 100 and reloading a new superstrate 108 onto the superstrate chuck assembly 118. The shaping system 100 can include multiple parallel subsystems some of which may be paused while others continue to operate. For example, the shaping system 100 can include one fluid dispenser 122 and multiple shaping heads, in which case stopping the shaping process can include stopping use of one of the shaping heads while other shaping heads continue to operate. Stopping the shaping process can include stopping operation of the fluid dispenser.

The image analysis software determines where spread front distortion is visible based on the distorted spread front that is translated into a rectangular strip and outputted from the machine learning model. Thus, calculating the radius at different angles for a video taken over a time 1 to M will reveal shorter radiuses where the spread front distortion exists as well as the angles at which the spread front distortion occurs. The angle θ may be any angle from 0 to 360 degrees. The measurements of multiple radiuses are taken at incremental values for θ. Annular cropping of the interference fringes and transformed into polar space (r,θ). A line fitted to the interference fringes and a break in the line is where a large particle is detected. The impact of a smaller particle on a zoomed in portion of an interference fringe, the particle will typically cause a bend in the interference fringe that has a larger deviation than the typical curvature of the interference fringe. A peak or a break in the graph may indicate where the spread front distortion exists. Some spread front distortion is okay and expected due to substrate and pattern non-uniformity. Unexpected spread front distortions that are beyond expected values can be indicative of cleanliness issues either on the superstrate or the substrate.

The present disclosure provides a significant advantage for a user to monitor the spread front for any abnormalities in real-time by observing kinks in the interference fringe. Real-time analysis is enabled by narrowing the scope of information that is analyzed around only the spread front. This is achieved by subtracting a previous image from any current image that is analyzed to emphasize the area near the spread front and interference fringe. This method also takes into account the variable speed at which the spread front spreads along the substrate. The object detection method of the present disclosure determines the radius and center coordinates of the spread front by tracing a radial lines from the substrate in the image, fitting the extrema to a circle using a fitting method, discarding any outliers and extracting annulus that contains the spread front by extracting intensity lines along every pixel in the circumference of the circle. Each extracted segment becomes a column in the final image. Essentially, the present disclosure identifies the location of the spread front in every image and transforms the spread front from polar coordinates to Cartesian coordinates which may then be passed to a machine learning model to detect any abnormalities in real-time.

A method of manufacturing an article (semiconductor integrated circuit device, liquid crystal display device, and the like) as an article includes a process of forming a pattern and/or planarizing on a substrate (wafer, glass plate, template, and film wafer) by using the shaping system 100 described above. In addition, the manufacturing method described above may include a process of etching the substrate on which a pattern is formed. In a case of manufacturing other articles such as electronic devices, patterned media (recording media), or optical devices, MEMS devices, the manufacturing method may include other processes which machine the substrate on which the pattern is formed instead of etching. The method of manufacturing an article of the embodiment is advantageous in terms of at least one of performance, quality, productivity, and production cost or articles in comparison with the method of the related art. The article produced by the method of manufacturing is an article that is manufactured on or from the substrate using a plurality of processes. Non-limiting examples of such an article include: an electrical circuit element, an optical element, a microelectromechanical system (MEMS), a recording element, a sensor, a mold, a template, an integrated circuit, a power transistor, a charge coupled-device (CCD), an image sensor, a microfluidic device, or the like. The method of manufacturing an article can include multiple processes such as semiconductor manufacturing processes. Well known semiconductor processing steps can be used in the method of manufacturing an article. Non-limiting examples of such semiconductor processes which can be performed in method of manufacturing an article include: inspection, curing, oxidation, layer formation, patterning, developing, cleaning, deposition, doping, planarization, etching, formable material removal, testing, singulating, bonding, and packaging.

### Second Embodiment

A method of monitoring the spread front according to a second embodiment is identical to the method described above except for steps S40-S70 described above. This second embodiment, takes advantage of single instruction multiple threads parallel processing architectures. The method includes receiving an initial contact point of the superstrate with formable material on the substrate.

For each image i at time index i, a radius is calculated for a subset of the pixels of the pixels in the image i from the initial contact point. The subset of pixels may include all of the pixels in the image or just those pixels which have a high likelihood of including the interference fringes. For each time index i there is a range of pixels within a radius of 1-30 mm in which the interference fringes are expected to be in.

For each time index i, a series of buckets of radii are formed having a small range of radii. Each pixel in this subset of pixels is associated with one of these radii buckets. Each radii bucket has associated radii bucket intensity value and an associated radii bucket count value.

After the radii for each pixel is calculated the intensity value of that pixel is added to the appropriate radii bucket intensity value and the radii bucket count is incremented. Once this has been done for each pixel in the subset of pixels an average radial intensity for each radial bucket can be calculated. Other methods of calculating the average radial intensity may also be used.

Once the average radial intensity over the radial buckets is calculated the average radial intensity is formed. Radial locations of extrema values (maximum average intensity and/or minimum average intensity) of the average radial intensity are then determined. The radial locations of the extrema are then used as the average radius R in step S80. In an embodiment, an average of the maximum and minimum radial locations is used as the average radius R. In alternative embodiments the maximum or minimum radial locations can also be used as the radial locations. This method works best when the image used during the steps above represents temporal changes in intensity from the set of interference fringes when forming the film.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

The above-described exemplary embodiments are merely specific examples for carrying out the present disclosure. The technical scope of the present disclosure should not be interpreted in a limited way due to these embodiments. The present disclosure can be carried out in various forms without departing from the technical idea or the main features thereof. For example, any combination of the exemplary embodiments is also included in the disclosed contents of the present disclosure.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method for monitoring a spread front using a spread camera to detect an abnormality, the method comprising:
receiving a series of images of interference fringes formed by reflections off a superstrate and a substrate as the superstrate conforms to the substrate while forming a film on the substrate with the superstrate;
for each image in the series of images, extracting an annular set of pixels that form an annular shape including one or more of the interference fringes;
converting each of the annular set of pixels into one or more rectangular sets of pixels of a rectangular shape;
detecting a probability of an abnormality in any of the one or more rectangular sets of pixels; and
reporting the probability.

2. The method of claim 1, wherein extracting the annulus set of pixels comprises:
identifying extrema in each of multiple radial series of pixels to form a set of extrema; and
identifying the annulus set of pixels based on a circle fitted to the set of extrema.

3. The method of claim 1, further comprising curing a planarization layer between the substrate and the superstrate when the probability is low.

4. The method of claim 1, further comprising removing a sandwich when the probability is high, wherein the sandwich includes: the substrate, the superstrate, and formable material between the substrate and the superstrate.

5. The method of claim 1, wherein each image from the series of images represents temporal changes in intensity from the set of interference fringes when forming the film.

6. The method of claim 1, wherein detecting the probability of the abnormality is performed using a computer vision machine learning model.

7. The method of claim 1, wherein a previous image is subtracted from a current image from the series of images to isolate an interference fringe associated with the spread front.

8. The method of claim 1, wherein the annular set of pixels in the sequence is unrolled into a rectangular set of pixels to be inputted into a computer vision machine learning model.

9. The method of claim 8, further comprising:
slicing the rectangular set of pixels into regions; and
inputting the regions into the computer vision machine learning model.

10. The method of claim 9, wherein the computer vision machine learning model is a pre-trained neural network.

11. The method of claim 1, wherein the series of images are a video initiating prior to or at the point of contact between the superstrate and the substrate.

12. The method of claim 1, wherein each image in the series of images represents a rate at which the interference fringes change as the spread front spreads from point of contact between the superstrate and the substrate in real-time.

13. The method of claim 1, wherein the annular set of pixels that form an annular shape are extracted by identifying a center position of a first interference fringe and a radius of the first interference fringe.

14. The method of claim 13, wherein the center position and the radius are identified by locating extrema along each of three or more radial lines in each image from the series of images.

15. The method of claim 13, wherein the center position and the radius are determined by identifying at least eight or more points along at least eight radial lines in each image from the series of images.

16. The method of claim 15, wherein the at least eight or more points are equidistant from each other.

17. The method of claim 1, further comprising:
manufacturing one or more articles, wherein manufacturing the one or more articles includes:
depositing drops of formable material on the substrate;
bringing a shaping surface of one of the superstrate into contact with the formable material that has been deposited on the substrate;
after bringing the shaping surface into contact with the formable material that has been deposited on the substrate, curing the formable material that has been deposited on the substrate; and
after curing the formable material that has been deposited on the substrate, processing the substrate so as to manufacture the one or more articles.

18. A device for monitoring a spread front using a spread camera to detect an abnormality, the device comprising:
a spread image camera to generate a series of images of interference fringes formed by reflections off a superstrate and a substrate as the superstrate conforms to the substrate while forming a film;
one or more computer-readable storage media; and
one or more processors that are in communication with the one or more computer-readable storage media and that cooperate with the one or more computer-readable storage media to cause the device to perform operations comprising:
extracting an annular set of pixels that form an annular shape including one or more of the interference fringes for each image in the series of images;
converting each of the annular set of pixels into one or more rectangular sets of pixels of a rectangular shape;
detecting a probability of an abnormality in any of the one or more rectangular sets of pixels; and
reporting the probability.

19. The method of claim 1, wherein:
the superstrate has one of:
an unpatterned shaping surface, and
a patterned shaping surface;
the film formed with the unpatterned shaping surface is a planarization layer; and
the film formed with the patterned shaping surface is a patterned layer.

20. The method of claim 1, further comprising:
curing a planarization layer between the substrate and the superstrate;
in a case wherein the probability is high, performing one or more of the following steps:
removing the planarization layer from the substrate;
swapping the superstrate with a new superstrate; and
pausing jetting of a subsequent wafer until the superstrate has been swapped.
